(19) United States
(12) Patent Application Publication
(10) Pub. No.: US 2016/0049340 A1
(43) Pub. Date: Feb. 18, 2016

(54) STRESS SENSOR FOR A SEMICONDUCTOR DEVICE

(71) Applicant: QUALCOMM INCORPORATED, San Diego, CA (US)

(72) Inventors: Vidhya Ramachandran, San Diego, CA (US); Urmi Ray, Ramona, CA (US)

(21) Appl. No.: 14/460,805

(22) Filed: Aug. 15, 2014

(51) Int. Cl. H01L 21/66; H01L 23/48; G01B 7/16; H01L 23/00

(52) U.S. Cl. CPC H01L 22/14; H01L 24/81; H01L 24/17; H01L 22/34; H01L 23/562; H01L 23/481; G01B 7/16; H01L 2224/16227; H01L 2924/0549; H01L 2924/01049; H01L 2924/0105; H01L 2224/023; H01L 2224/81908; H01L 2924/35; H01L 2924/384; G01B 2210/56

(57) ABSTRACT

In a particular embodiment, an apparatus includes a stress sensor located on a first side of a semiconductor device. The apparatus further includes circuitry located on a second side of the semiconductor device. The stress sensor is configured to detect stress at the semiconductor device. In another particular embodiment, a method includes receiving data from a stress sensor located on a first side of a packaged semiconductor device. The packaged semiconductor device includes circuitry located on a second side of the packaged semiconductor device. The data indicates stress detected by the stress sensor. The method further includes performing a test associated with the packaged semiconductor device based on the data.

### I. FIELD

The present disclosure is generally related to stress detection for a semiconductor device.

### II. DESCRIPTION OF RELATED ART

An electronic device may include one or more integrated circuits that perform operations. To assemble an electronic device, an integrated circuit may be positioned within a carrier device (or “package”) and then attached to a surface, such as a circuit board. A packaged integrated circuit may have a “flip chip” configuration. In a flip chip configuration, the integrated circuit may be “flipped” into the package by attaching a top layer of the integrated circuit to a surface of the package (instead of attaching a substrate of the integrated circuit to the surface of the package).

The assembly process may impose mechanical stress on the integrated circuit, and the mechanical stress may cause operation of the integrated circuit to fail or to deviate from a design specification of the integrated circuit. For example, as integrated circuits are thinned to enable smaller device sizes, transistors may become more sensitive to stress, which may cause operation of the transistors to fail or to deviate from a design specification associated with the integrated circuit (or “go out of spec”).

### III. SUMMARY

A backside stress sensor may be formed on a semiconductor device to enable detection of stress imposed on a particular region of the semiconductor device, such as strain associated with an assembly process (e.g., a flip chip packaging process). By forming the stress sensor on the backside of the semiconductor device, the stress sensor can be positioned opposite to or adjacent to (e.g., “directly below”) sources of stress and/or “stress-sensitive” circuitry, such as analog circuitry. The stress sensor may therefore be positioned to detect stress more accurately than a front-side stress sensor that is not aligned with a stressed region (e.g., that is located at the periphery of the front-side of the device or outside a “stress-sensitive” circuit). Such a stress sensor is particularly useful for a “thinned” semiconductor device that has a reduced thickness. To illustrate, the backside stress sensor may be positioned below (e.g., opposite to) a flip chip bump that potentially causes strain (e.g., warpage) to a particular region of (but not all of) the semiconductor device. The backside stress sensor may be positioned (e.g., may be vertically “aligned with” the flip chip bump) to detect the warpage. A conventional front-side stress sensor located at the periphery of the front-side of the device or not aligned with the flip chip bump may not be positioned to accurately detect the warpage (e.g., the front-side stress sensor may be located near a region of the device that is not strained, and the front-side stress sensor may therefore not detect the warpage or measurement of the warpage may be less accurate).

In a particular embodiment, an apparatus includes a stress sensor located on a first side (e.g., a backside) of a semiconductor device. The apparatus further includes circuitry located on a second side (e.g., a frontside) of the semiconductor device. The stress sensor is configured to detect stress at the semiconductor device.

In another particular embodiment, a method includes receiving data from a stress sensor located on a first side of a packaged semiconductor device. The packaged semiconductor device includes circuitry located on a second side of the packaged semiconductor device. The data indicates stress detected by the stress sensor. The method further includes performing a test associated with the packaged semiconductor device based on the data.

In another particular embodiment, a computer-readable medium stores instructions that are executable by a processor to initiate or control operations during a fabrication process. The operations include forming a stress sensor on a first side of a semiconductor device. The operations further include forming circuitry on a second side of the semiconductor device. The operations also include forming a structure within the semiconductor device to provide data indicating stress detected by the stress sensor to an interface during a test associated with the semiconductor device.

In another particular embodiment, an apparatus includes means for sensing stress at a semiconductor device. The means for sensing stress is located on a first side of the semiconductor device. The apparatus further includes means for performing circuit operations. The means for performing circuit operations is located on a second side of the semiconductor device.

One particular advantage provided by at least one of the disclosed embodiments is that by including a stress sensor at a first side of a semiconductor device, more space is available at a second side of the semiconductor device for the placement of circuitry as compared to semiconductor devices that include stress sensors on the same side as the circuitry. In addition, the stress sensor in certain scenarios may provide more accurate measurements. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of a particular illustrative embodiment of a packaged semiconductor device having a stress sensor.

FIG. 2 is a diagram of a first embodiment of a device that can be implemented within a package to produce a packaged semiconductor device.

FIG. 3 is a diagram of a second embodiment of a device that can be implemented within a package to produce a packaged semiconductor device.

FIG. 4 is a flow diagram of an illustrative embodiment of a method of forming a semiconductor device having a stress sensor.

FIG. 5 is a flow diagram of another illustrative embodiment of a method of forming a semiconductor device having a stress sensor.

FIG. 6 is a flow diagram of an illustrative embodiment of a method of assembling a semiconductor device having a stress sensor.

FIG. 7 is a flow diagram of an illustrative embodiment of a method of testing a semiconductor device having a stress sensor.

FIG. 8 is a block diagram of an electronic device including a semiconductor device having a stress sensor.

FIG. 9 is a flow diagram of particular illustrative embodiment of a manufacturing process to manufacture electronic devices that include semiconductor devices having stress sensors.

### V. DETAILED DESCRIPTION

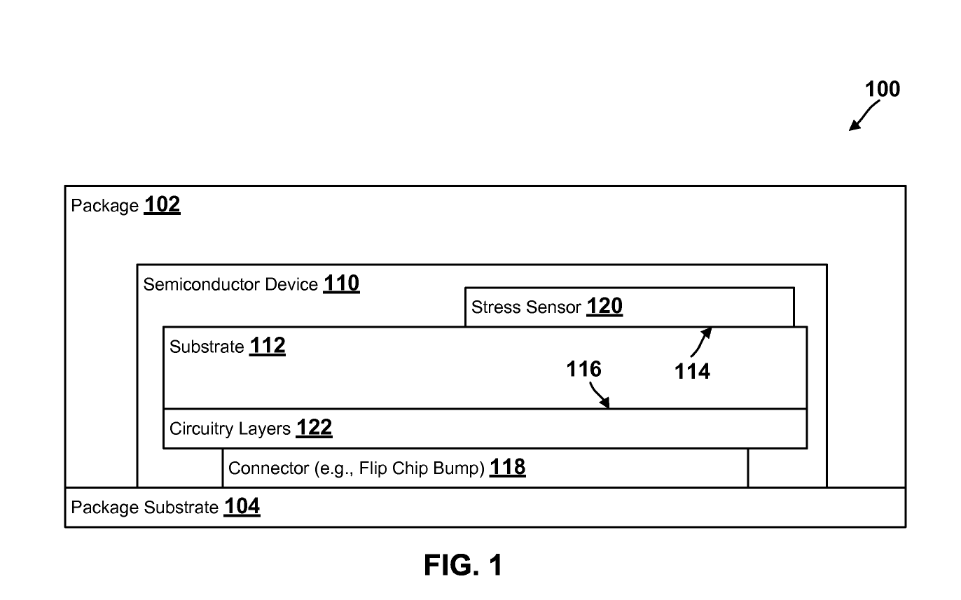

Referring to FIG. 1, a diagram of a packaged semiconductor device 100 is depicted. The packaged semiconductor device 100 includes a package 102 and a semiconductor device 110. The package 102 may include a package substrate 104 and may encase the semiconductor device 110. The package 102 may further include metal, plastic, ceramic, another material for encasing the semiconductor device 110, or any combination thereof.

As illustrated in FIG. 1, the semiconductor device 110 may be packaged or integrated into the package 102. In a particular embodiment, the semiconductor device 110 is integrated into the package 102 in a “flip chip” configuration as described herein.

The semiconductor device 110 may include a first side and a second side. For example, the first side of the semiconductor device 110 may include portions of the semiconductor device 110 that are closer to a first surface 114 of the substrate 112 than a second surface 116 of the substrate 112. The second side of the semiconductor device 110 may include portions of the semiconductor device 110 that are closer to the second surface 116 of the substrate 112 than the first surface 114 of the substrate 112.

The semiconductor device 110 may further include a stress sensor 120, the substrate 112, one or more circuitry layers 122, and a connector 118. As illustrated in FIG. 1, the stress sensor 120 may be located at the first side of the semiconductor device 110. The one or more circuitry layers 112 are located at the second side of the semiconductor device 110. The first side of the semiconductor device 110 may be a backside (e.g., opposite from the circuitry layers 122) of the semiconductor device 110.

The stress sensor 120 may be configured to detect stress at the semiconductor device 110. For example, the stress sensor 120 may be configured to detect stress imposed on the one or more circuitry layers 122. The stress sensor 120 may include a Piezo-resistive film layer (such as a semiconductor, a metal or a transparent conducting oxide (TCO)). Particular electrical characteristics of the Piezo-resistive film layer may depend on an amount of mechanical stress applied to the stress sensor 120. For example, stress applied to the Piezo-resistive film layer (e.g., stress during an assembly process) may cause the Piezo-resistive film layer to exhibit more or less resistance when an electrical current is applied to the oxide film layer. In a particular embodiment, the Piezo-resistive film layer includes indium tin oxide. Because the stress sensor 120 is located on the first side (e.g., the backside) of the semiconductor device 110, the stress sensor 120 is referred to as a backside stress sensor.

The semiconductor device 110 may include circuitry located on the second side (e.g., a frontside) of the semiconductor device 110. For example, the one or more circuitry layers 122 may include circuits to perform operations related to the semiconductor device 110. The circuits may include active devices, passive devices, routing structures, coupling structures, or any combination thereof.

The connector 118 may couple the semiconductor device 110 to the package substrate 104. For example, the connector 118 may include one or more flip chip bumps. The one or more flip chip bumps may couple the semiconductor device 110 to the package substrate 104.

During operation, the stress sensor 120 may be configured to detect stress associated with the semiconductor device 110, such as stress imposed on the one or more circuitry layers 122 by the connector 118. For example, stress may occur during packaging or integration of the semiconductor device 110 into the package 102, during a board assembly process (e.g., connecting the packaged semiconductor device 100 to a circuit board), or during another process associated with the semiconductor device 110.

By positioning the stress sensor 120 at the first side of the semiconductor device (e.g., on an opposite side from the one or more circuitry layers 122 and the connector 118), the stress sensor 120 may be aligned with one or more particular portions (e.g., one or more circuits) of the one or more circuitry layers 122 and/or the connector 118. The position of the stress sensor 120 may enable measurement of stress associated with the particular portions during assembly of the packaged semiconductor device 100.

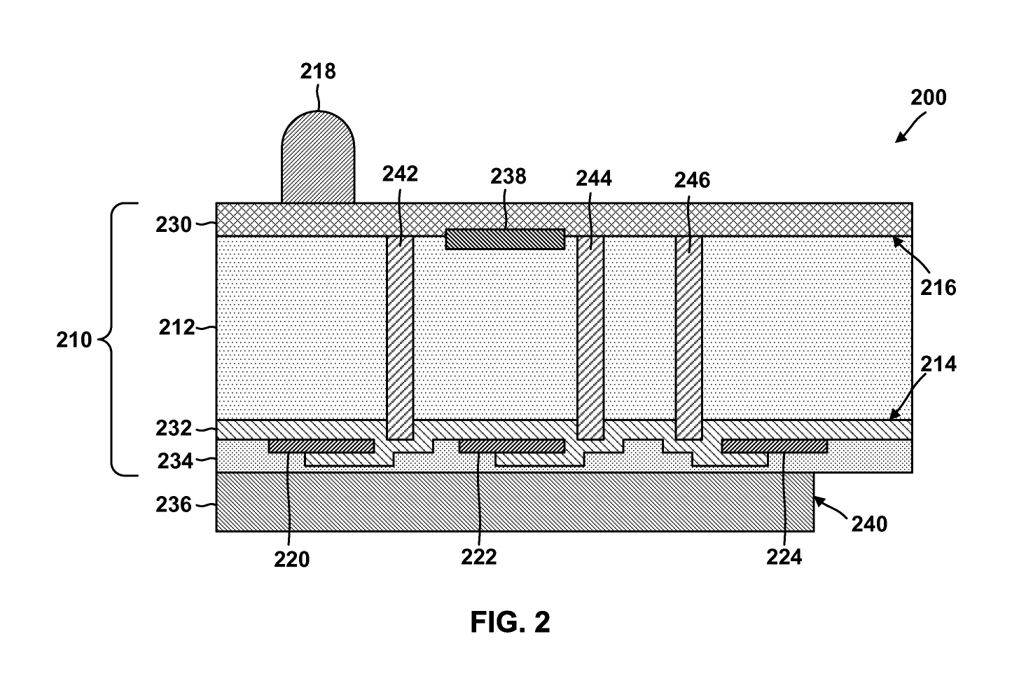

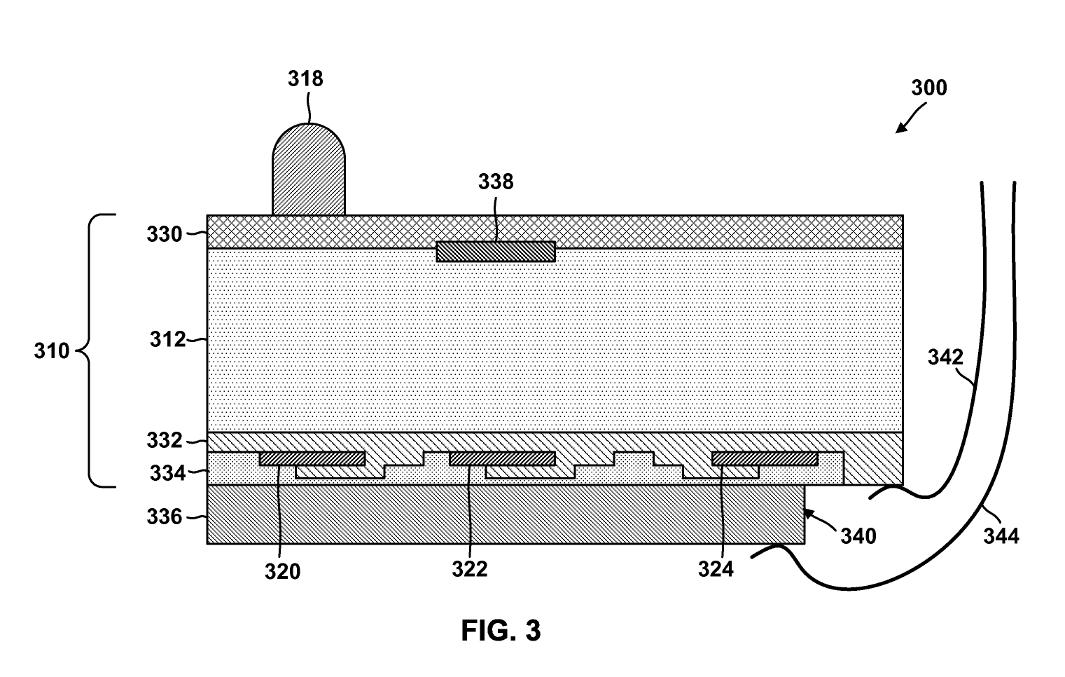

Although the semiconductor device 110 is depicted as including one stress sensor (e.g., the stress sensor 120), the semiconductor device 110 may include more than one stress sensor in other embodiments, such as described with reference to FIGS. 2 and 3. Further, although the packaged semiconductor device 100 is depicted in FIG. 1 as including one semiconductor device, in other embodiments, multiple semiconductor devices may be integrated within a package. Examples of multiple semiconductor devices that can be integrated within a package are described further with reference to FIGS. 2 and 3.

Referring to FIG. 2, a diagram of a first embodiment of a device 200 is depicted. The device 200 may include a first semiconductor device 210 and a second semiconductor device 236. Although the device 200 is depicted as including two semiconductor devices, in other embodiments the device 200 may include fewer than two or more than two semiconductor devices. In a particular embodiment, the device 200 may be integrated within the package 102 of FIG. 1 to produce a system-in-package (SiP) device.

The first semiconductor device 210 includes one or more circuitry layers 230, a substrate 212, a redistribution layer 232, and a passivation layer 234. The redistribution layer 232 and the passivation layer 234 may be located on a first side of the first semiconductor device 210. For example, the redistribution layer 232 and the passivation layer 234 may be closer to a first surface 214 of the substrate 212 than to a second surface 216. The one or more circuitry layers 230 may be located on a second side of the first semiconductor device 210. For example, the one or more circuitry layers 234 may be closer to the second surface 216 of the substrate 212 than to the first surface 214. The first side of the first semiconductor device 210 may be a backside of the first semiconductor device 210 and the second side of the first semiconductor device 210 may be a frontside of the first semiconductor device 210.

The one or more circuitry layers 230 may include circuits to perform operations related to the first semiconductor device 210. For example, the one or more circuitry layers 230 may include active devices, passive devices, routing structures, coupling structures, or any combination thereof. In an embodiment, the one or more circuitry layers 230 correspond to the one or more circuitry layers 122 of FIG. 1.

The redistribution layer 232 may include circuits to perform routing operations between multiple circuits of the first semiconductor device 210 and/or between the first semiconductor device 210 and the second semiconductor device 240. The passivation layer 234 may be configured to reduce or prevent noise (e.g., crosstalk signals) between the first semiconductor device 210 and the second semiconductor device 236.

The first semiconductor device 210 further includes a first stress sensor 220 and a connector 218. In a particular embodiment, the connector 218 is a flip chip bump to enable the semiconductor device 210 to be coupled to a package substrate (e.g., the package substrate 104 of FIG. 1). For example, the connector 218 may correspond to the connector 118. In this example, the connector 218 may be used to connect the semiconductor device 210 to a package substrate (e.g., the package substrate 104 of FIG. 1) after mounting the semiconductor device 210 into the package 102 using a flip chip packaging technique. In another embodiment, the connector 218 may be a microbump to enable the first semiconductor device 210 to be coupled to another semiconductor device.

The first stress sensor 220 may be positioned on the backside of the first semiconductor device 210. The connector 218 and the first stress sensor 220 may be aligned such that stress imposed on the first semiconductor device 210 by the connector 218 may be detected by the first stress sensor 220. The connector 218 may correspond to the connector 118 of FIG. 1.

In a particular embodiment, the semiconductor device 210 may include a second stress sensor 222 and a second circuit 238 formed on the second side of the semiconductor device 210. The second circuit 238 may be part of the one or more circuitry layers 230. The second sensor 222 may be positioned on the backside of the semiconductor device 210 and the second circuit 238 may be positioned on the frontside. The second circuit 238 and the first stress sensor 220 may be aligned such that stress imposed on the second circuit 238 may be detected by the second stress sensor 222. The second circuit 238 may be an analog circuit. In an embodiment, the second circuit 238 may correspond to the one or more circuitry layers 122 of FIG. 1.

In a particular embodiment, the semiconductor device 210 may include a third stress sensor 224. The third stress sensor 224 of the first semiconductor device 210 may be aligned with an edge 240 of the second semiconductor device 236. The third stress sensor 224 may be configured to detect stress imposed on the semiconductor device 210 by the second semiconductor device 236. For example, during an assembly process, the second semiconductor device 236 may be attached to the semiconductor device 210. The assembly process may cause higher stress at a portion of the first semiconductor device 210 in contact with the edge 240 of the second semiconductor device 236 than at other portions of the first semiconductor device 210.

The semiconductor device 210 may further include one or more vias through the substrate 212. For example, as depicted in FIG. 2, the semiconductor device 210 may include a first via 242, a second via 244, and a third via 246. One or more of the vias 242-246 may enable stress measurements from one or more of the stress sensors 220-224 to be provided to the circuitry layers 230.

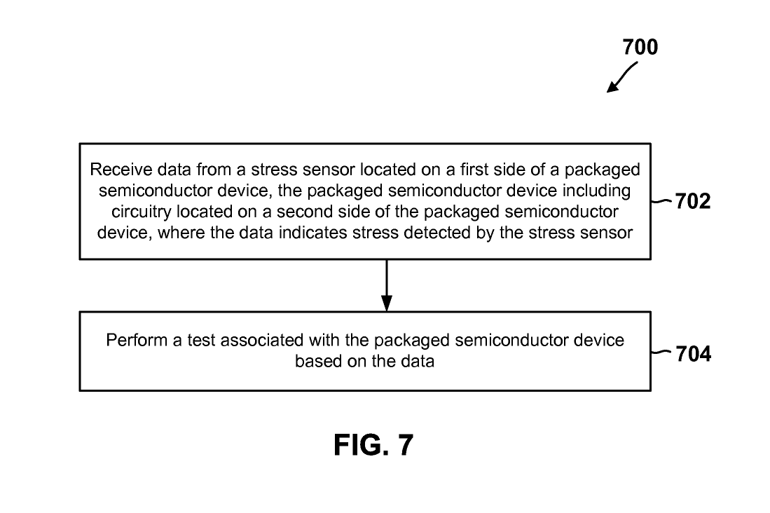

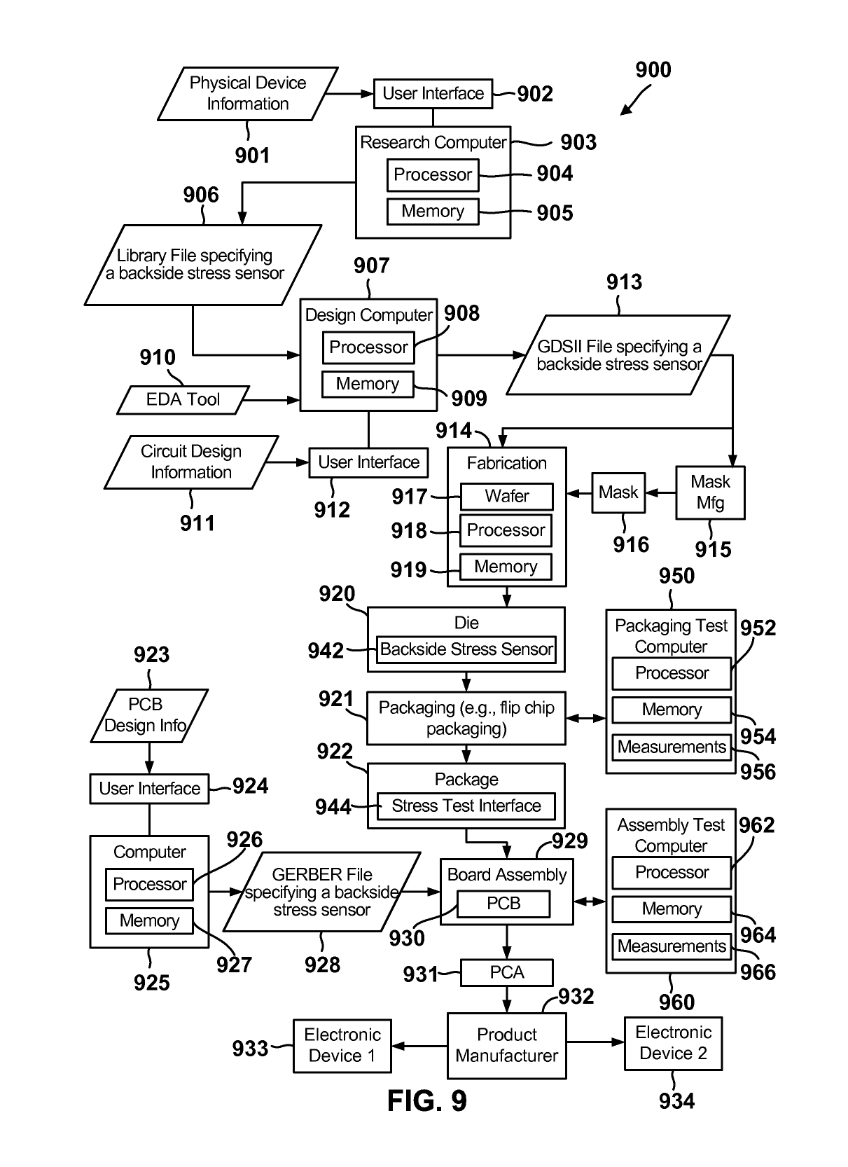

For example, during a testing operation (e.g., during testing of the device 200), the redistribution layer 232 may be configured to route stress information from the first stress sensor 220 to the first via 242. The first via 242 may be configured to route the stress information to the one or more circuit layers 230. The one or more circuit layers 230 may be configured to route the stress information to the connector 218 or to a circuit of the one or more circuit layers 230 that is accessible by an interface. As an example, the interface may be used to provide the stress information to a testing computer as described further with reference to FIGS. 7 and 9. Similarly, second stress information from the second stress sensor 222 may be accessible to the interface via the redistribution layer 232, the second via 244, and the one or more circuitry layers 230. Third stress information from the third stress sensor 224 may be accessible to the interface via the redistribution layer 232, the third via 246, and the one or more circuitry layers 230.

By positioning one or more of the stress sensors 220-224 on the first side of the semiconductor device 210 and by aligning the stress sensors 220-224 with particular portions of the semiconductor device (e.g., the connector 218, the second circuitry 238, and the edge 240 of the second semiconductor device 236), the one or more stress sensors 220-224 may detect stress associated with each of the particular portions during assembly of the packaged semiconductor device 100.

Referring to FIG. 3, a diagram of a second embodiment of a device 300 is depicted. The device 300 includes a first semiconductor device 310 and a second semiconductor device 336. The device 300 may correspond to the packaged semiconductor device 100 of FIG. 1 and/or the device 200 of FIG. 2. Although the device 300 is depicted as including two semiconductor devices, in other embodiments the device 300 may include fewer than two or more than two semiconductor devices.

The first semiconductor device 310 includes one or more circuitry layers 330, a substrate 312, a redistribution layer 332, and a passivation layer 334. The one or more circuitry layers 330, the substrate 312, and the passivation layer 334 may correspond to the one or more circuitry layers 230, the substrate 212, and the passivation layer 234 of FIG. 2, respectively.

The first semiconductor device 310 further includes a first stress sensor 320, a second stress sensor 322, and a third stress sensor 324. The first stress sensor 320 may be aligned with a connector 318 and may correspond to the first stress sensor 220 of FIG. 2. The second stress sensor 322 may be aligned with second circuitry 338 and may correspond to the second stress sensor 222 of FIG. 2. The third stress sensor 324 may be aligned with an edge 340 of the second semiconductor device 336 and may correspond to the third stress sensor 234 of FIG. 1. The first stress sensor 320, the second stress sensor 322, and the third stress sensor 324 may be positioned on a backside of the semiconductor device 310. The first circuitry 318 and the second circuitry 338 may be positioned on a frontside of the semiconductor device 310.

The device 300 may be attached to a first lead 324 (e.g., a wire) and a second lead 344. The first lead 324 may be coupled to the redistribution layer 332 of the first semiconductor device 310. The second lead 344 may be connected to the second semiconductor device 336. In an embodiment, additional leads may be connected to additional semiconductor devices of the device 300.

During a testing operation, the redistribution layer 332 may be configured to route information from one or more of the stress sensors 320-324 to the first lead 342. The first lead 342 may be configured to route the stress information to an interface of a package, such as the package 102 of FIG. 2. The interface may be used for providing the stress information to a testing computer as described further with reference to FIGS. 7 and 9. Further, the second lead 344 may provide stress information from the second semiconductor device 336 to the interface. The interface may include an automated test equipment (ATE) interface, another type of semiconductor device testing interface, or a combination thereof.

By configuring the redistribution layer 332 to route stress information to the first lead 342, the stress information may be provided to an interface without using vias in the substrate 312. Further, by providing stress information from the second semiconductor device 336 to the interface via the second lead 344, additional circuitry (e.g., to route the stress information from the second semiconductor device to the interface) need not be formed at the first semiconductor device 310.

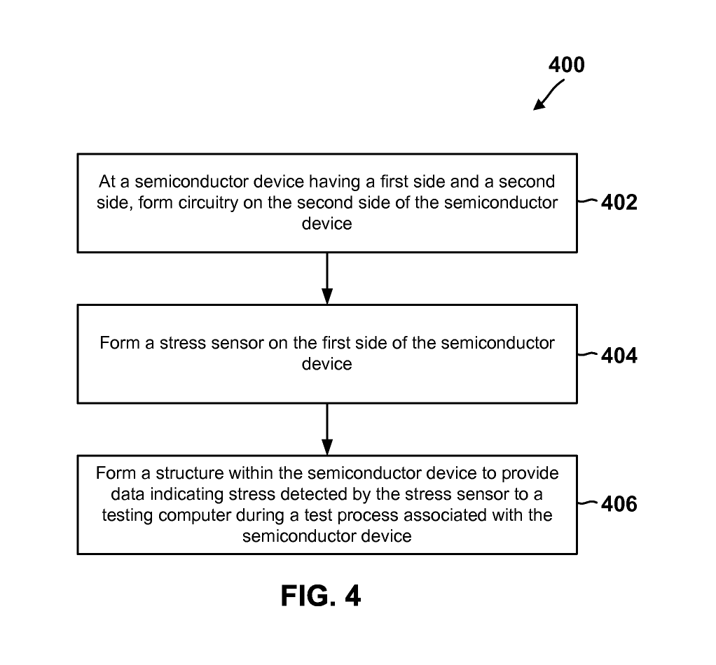

Referring to FIG. 4, a flow diagram of a first illustrative embodiment of a method 400 of forming a semiconductor device is depicted. The semiconductor device may include the semiconductor device 110 of FIG. 1, the semiconductor device 210 of FIG. 2, or the semiconductor device 310 of FIG. 3. The semiconductor device includes a first side (e.g., a backside) and a second side (e.g., a front side).

The method 400 includes forming circuitry on the second side of the semiconductor device, at 402. For example, referring to FIG. 1, the one or more circuitry layers 122 may be formed on a second side (e.g., a front side) of the semiconductor device 110. The second side may include portions of the semiconductor device 110 that are nearer to the second surface 116 of the substrate 112 than to the first surface 114.

The method 400 further includes forming a stress sensor on the first side of the semiconductor device, at 404. For example, referring to FIG. 1, the stress sensor 120 may be formed on a first side (e.g., a backside) of the semiconductor device 110. The first side may include portions of the semiconductor device 110 that are closer to a first surface 114 of the substrate 112 than a second surface 116 of the substrate 112. Forming the stress sensor may include depositing a resistive material on the substrate 112. Alternatively, forming the stress sensor may include depositing the resistive material on one or more layers deposited on the substrate 112. The resistive material may include an oxide thin film layer. Additional circuitry may be formed to enable test operations. For example, referring to FIG. 1, an analog to digital converter may be formed in the one or more circuitry layers 122 to digitize one or more signals generated by the stress sensor 120. The digitized signals may be provided to a test computer during testing of the semiconductor device 110, as an illustrative example.

The method 400 may optionally also include forming a structure within the semiconductor device to provide data indicating stress detected by the stress sensor to a testing computer during a test process associated with the semiconductor device, at 406. For example, referring to FIG. 2, one or more of the vias 242-246 may be formed through the substrate 212. The one or more vias 242-246 may route data indicating stress detected by one or more of the sensors 220-224 to the one or more circuit layers 230. The one or more circuit layers 230 may be configured to route the stress information to the connector 218 or to a circuit of the circuit layers 230 accessible by the testing computer via an interface of the package 102. Alternatively, referring to FIG. 3, one or more circuits may be formed in the redistribution layer 332 to route the data to the first lead 342. The data may be accessible to the interface via the first lead 342.

The method 400 may be used to form a semiconductor device with one or more stress sensors on a first side of the semiconductor device aligned with particular portions (e.g., a particular connector, a particular circuit, and/or a particular structure) on a second side of the semiconductor device. The one or more stress sensors may enable detection of stress associated with the particular portions during assembly of a packaged device that includes the semiconductor device.

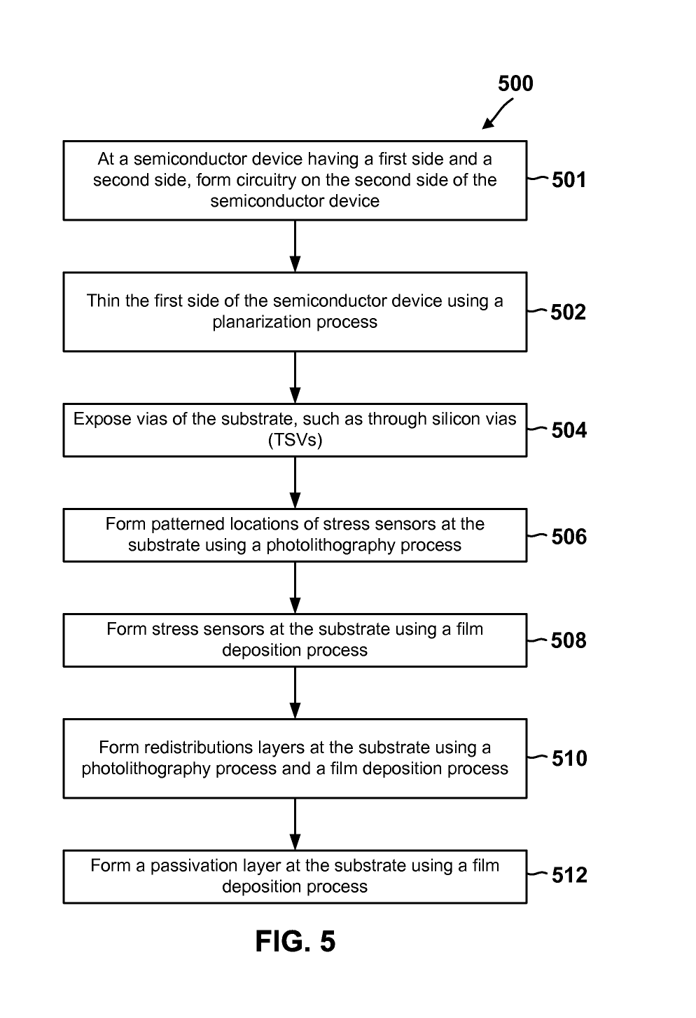

Referring to FIG. 5, a flow diagram of an illustrative embodiment of a method 500 of forming a semiconductor device is depicted. The semiconductor device may include the semiconductor device 110 of FIG. 1, the semiconductor device 210 of FIG. 2, or the semiconductor device 310 of FIG. 3. The semiconductor device includes a substrate having a first side (e.g., a backside) and a second side (e.g., a front side).

The method 500 may include forming circuitry on the second side of the semiconductor device, at 501. To illustrate, the circuitry may correspond to any of the one or more circuitry layers 122, the one or more circuitry layers 230, the second circuit 238, or the one or more circuitry layers 330, as illustrative examples.

The method 500 may further include thinning the first side of the semiconductor device using a planarization process, at 502. The planarization process may be applied to a substrate of the semiconductor device. For example, referring to FIG. 1, the substrate 112 may be thinned to reduce a width of the semiconductor device 110 (e.g., to enable the semiconductor device 110 to be integrated within the package 102).

The method 500 may include exposing vias of the substrate, such as through silicon vias (TSVs), at 504. For example, referring to FIG. 2, during formation of the first semiconductor device 210, the substrate 212 may be thinned to expose one or more of the vias 242-246.

The method 500 may also include forming patterned locations of stress sensors at the substrate using a photolithography process, at 506. For example, referring to FIG. 2, patterned locations of stress sensors may be formed at the substrate 212.

The method 500 may include forming stress sensors at the substrate using a film deposition process, at 508. For example, one or more of the stress sensors 220-224 of FIG. 2 may be formed at the substrate 212 using a film deposition process. In a particular embodiment, an oxide thin film layer may be deposited at the substrate 212 to form one or more of the stress sensor 220-224. Additional circuitry may be coupled to the resistive material to enable test operations using signals generated by the stress sensor 120, such as measurement circuitry, routing circuitry, an analog to digital converter, etc.

The method 500 may further include forming redistribution layers at the substrate using a photolithography process and a film deposition process, at 510. For example, referring to FIG. 2, the redistribution layer 234 may be formed at the substrate 212 using photolithography and a film deposition process.

The method 500 may also include forming a passivation layer at the substrate using a film deposition process, at 512. For example, referring to FIG. 2, the passivation layer 234 may be formed at the substrate 212.

The method 500 may be used to form a semiconductor device with one or more stress sensors on a first side of the semiconductor device, where the one or more sensors are aligned with particular portions on a second side of the semiconductor device. The one or more stress sensors may enable detection of stress associated with the particular portions during assembly of a packaged device that includes the semiconductor device. One or more structures described with regard to FIG. 5 (e.g., one or more vias or one or more redistribution layers) may enable test operations by providing data to a package interface during the test operations.

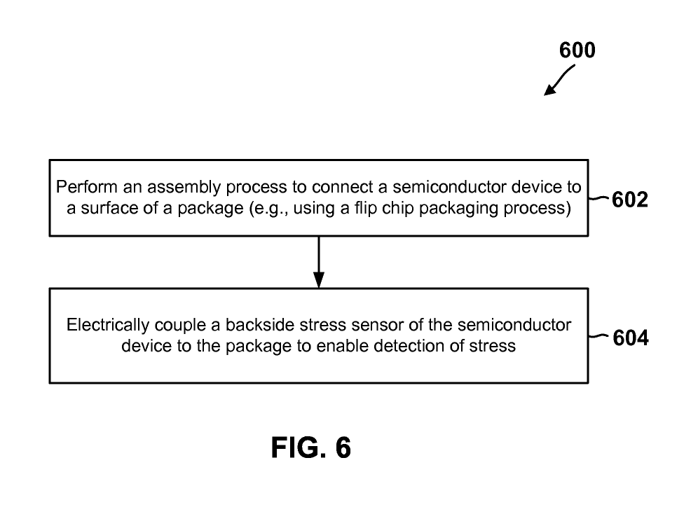

Referring to FIG. 6, a flow diagram of an illustrative embodiment of a method 600 of assembling a packaged device is depicted. The packaged device may correspond to the packaged semiconductor device 100 of FIG. 1.

The method 600 may include performing an assembly process to connect a semiconductor device to a surface of a package (e.g., using a flip chip packaging process), at 602. For example, referring to FIG. 1, the semiconductor device 110 may be connected to the package substrate 104 via the connector 118.

The method 600 may further include electrically coupling a backside stress sensor of the semiconductor device to the package to enable detection of stress, at 604. For example, referring to FIG. 2, one or more of the stress sensors 220-224 may be electrically connected to an interface of a package (e.g., the package 102 of FIG. 1), such as by connecting a trace of the package substrate 104 to the backside stress sensor and to the interface. Alternatively or in addition, electrically coupling the backside stress sensor to the interface of the package may include connecting a wire (e.g., the lead 342) between the backside stress sensor and the interface.

By electrically coupling the backside stress sensor to the package, testing may be enabled at the semiconductor device after the semiconductor device is packaged. For example, stress data may be provided by the stress sensor to a testing interface. The stress data may be compared to a stress threshold during a test associated with the semiconductor device, as described further with reference to FIG. 7.

The method 600 may be used to assemble a packaged device with one or more stress sensors and to enable measurement of stress associated with assembly of the packaged device. In an illustrative implementation, the stress sensors can be used to test the packaged device, as described further with reference to FIG. 7.

Referring to FIG. 7, a method of testing a semiconductor device having a stress sensor (or multiple stress sensors) is depicted and generally designated 700. The semiconductor device may include the semiconductor device 110 of FIG. 1, the semiconductor device 210 of FIG. 2, or the semiconductor device 310 of FIG. 3. The method 700 may be performed after assembly of the packaged device has occurred (e.g., after performing the method 600 of FIG. 6).

The method 700 may include receiving data from a stress sensor located on a first side of a packaged semiconductor device, at 702. The packaged semiconductor device includes circuitry located on a second side of the packaged semiconductor device. The data may indicate stress detected by the stress sensor. For example, referring to FIG. 1, a testing computer may receive data from the stress sensor 120 via an interface of the package 102. The data may correspond to an electrical property of the stress sensor. For example, the data may correspond to a resistance, a capacitance, another electrical property of the stress sensor, or any combination thereof. To illustrate, stress applied to the sensor may cause one or more electrical properties of the stress sensor to change.

The method 700 may further include performing a test associated with the packaged semiconductor device based on the data, at 704. For example, a test computer may compare the data to a stress threshold associated with the packaged semiconductor device to determine whether stress applied to the packaged semiconductor device (e.g., during an assembly process) exceeds the stress threshold. If the stress applied to the packaged semiconductor device exceeds the stress threshold, the packaged semiconductor device may be further tested and/or discarded. Examples of additional tests include testing functionality of one or more circuits of the packaged semiconductor device and/or testing connectivity of the one or more circuits.

In embodiments where the packaged semiconductor device includes multiple test sensors, the method 700 may be performed for each stress sensor. For example, data from each stress sensor may be received and one or more tests associated with the packaged semiconductor device may be performed based on the data from each stress sensor. In some embodiments, each stress sensor may correspond to a different stress threshold based on a location of the stress sensor within the packaged semiconductor device.

The method 700 may be used to detect stress associated with assembly of a packaged device. Because the stress sensor is located at the first side of the packaged semiconductor device, the stress sensor may be aligned with a particular portion of the second side of packaged semiconductor device. The position of the stress sensor may enable measurement of stress associated with the particular portion during assembly of the packaged semiconductor device.

By receiving the data from the stress sensor located on the first side (e.g., the backside) of the packaged semiconductor device, the testing computer may receive more accurate data than other implementations that receive data from a stress sensor located on the second side (e.g., the frontside).

The methods of FIGS. 4-7 may be initiated or controlled by a field-programmable gate array (FPGA) device, an application-specific integrated circuit (ASIC), a processing unit such as a central processing unit (CPU), a digital signal processor (DSP), a controller, another hardware device, a firmware device, or any combination thereof. As an example, the methods of FIG. 4-7 can be performed by one or more processors that execute instructions to control fabrication and testing equipment.

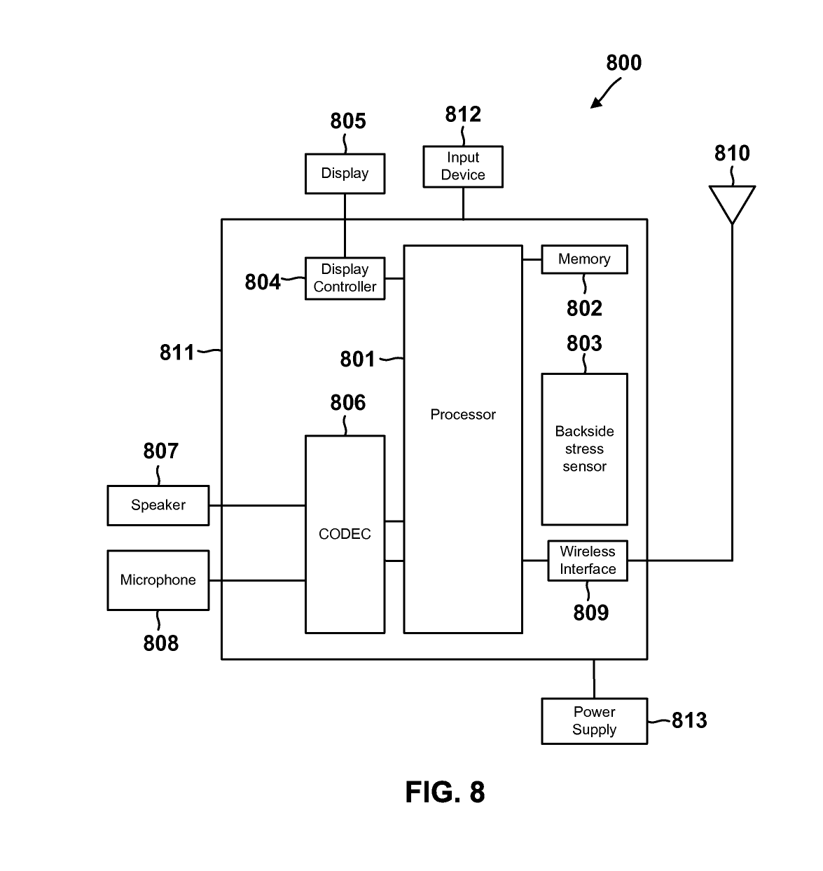

Referring to FIG. 8, a block diagram of a particular illustrative embodiment of an electronic device 800 is depicted. The electronic device 800 may include the packaged device 100 of FIG. 1, the device 200 of FIG. 2, the device 300 of FIG. 3, or a combination thereof.

The electronic device 800 includes a processor 801, such as a digital signal processor (DSP), coupled to a memory 802. The memory 802 includes instructions, such as computer-readable instructions or processor-readable instructions. The instructions may include one or more instructions that are executable by the processor 801.

FIG. 8 also shows a display controller 804 that is coupled to the processor 801 and to a display 805. A coder/decoder (CODEC) 806 can also be coupled to the processor 801. A speaker 807 and a microphone 808 can be coupled to the CODEC 806.

FIG. 8 also indicates that a wireless interface 809, such as a wireless controller, can be coupled to the processor 801 and to an antenna 810. In a particular embodiment, the processor 801, the display controller 804, the memory 802, the CODEC 806, and the wireless interface 809 are included in a system-on-chip (SoC) or a system-in-package (SiP) device 811. The system-in-package device 811 includes a backside stress sensor 803. For example, one or more devices of the system-in-package device 811 includes a semiconductor device. The semiconductor device may correspond to the semiconductor device 110 of FIG. 1, the first semiconductor device 210 of FIG. 2, or the first semiconductor device 310 of FIG. 3. The semiconductor device includes a stress sensor located at a backside of the semiconductor device as described with reference to FIGS. 1-3. The backside stress sensor 803 is usable to detect stress at the semiconductor device (e.g., stress associated with packaging and/or assembly of the semiconductor device).

In a particular embodiment, an input device 812 and a power supply 813 are coupled to the system-in-package device 811. Moreover, in a particular embodiment, as illustrated in FIG. 8, the display 805, the input device 812, the speaker 807, the microphone 808, the antenna 810, and the power supply 813 are external to the system-in-package device 811. However, each of the display 805, the input device 812, the speaker 807, the microphone 808, the antenna 810, and the power supply 813 can be coupled to a component of the system-in-package device 811, such as an interface or a controller. Although the backside stress sensor 803 is depicted as being external to other components of the electronic device 800, the backside stress sensor 803 may be included in any component of the electronic device 800 or a component coupled to the electronic device 800. For example, the backside stress sensor 803 may be included in the processor 801, the memory 802, the wireless interface 809, the power supply 813, the input device 812, the display 805, the display controller 804, the CODEC 806, the speaker 807, or the microphone 808. In a particular embodiment, one or more components of the electronic device 800 may be formed on or coupled to a same substrate (e.g., as a system-on-chip).

One or more of the disclosed embodiments may be implemented in a system or an apparatus, such as the electronic device 800, that may include a communications device, a fixed location data unit, a mobile location data unit, a mobile phone, a cellular phone, a satellite phone, a computer (e.g., a tablet, a portable computer, or a desktop computer). Alternatively or additionally, the device electronic 800 may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof.

In conjunction with one or more of the described embodiments of FIGS. 1-8, an apparatus is disclosed that includes means for sensing stress at a semiconductor device. The means for sensing stress may be located on a first side of the semiconductor device. The means for sensing stress at the semiconductor device may correspond to the stress sensor 120 of FIG. 1, one or more of the stress sensors 220-224 of FIG. 2, one or more of the stress sensors 320-324, or any combination thereof.

The apparatus also includes means for performing circuit operations. The means for performing circuit operations is located on a second side of the semiconductor device. The means for performing circuit operations may correspond to the one or more circuitry layers 122 of FIG. 1, the one or more circuitry layers 230 of FIG. 2, the circuitry 238 of FIG. 2, the one or more circuitry layers 330 of FIG. 3, the circuitry 338 of FIG. 3, the system-in-package 811 (or components thereof) of FIG. 8, or any combination thereof.

The foregoing disclosed devices and functionalities may be designed and configured into computer files (e.g. RTL, GDSII, GERBER, etc.) stored on computer-readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 9 depicts a particular illustrative embodiment of an electronic device manufacturing process 900.

Physical device information 901 is received during the manufacturing process 900, such as at a research computer 903. The physical device information 901 may include design information representing at least one physical property of a semiconductor device that includes a backside sensor, such as the semiconductor device 110 of FIG. 1, the semiconductor devices 210, 236 of FIG. 2, the semiconductor devices 310, 336 of FIG. 3, or a combination thereof. For example, the physical device information 901 may include physical parameters, material characteristics, and structure information that is entered via a user interface 902 coupled to the research computer 903. The research computer 903 includes a processor 904, such as one or more processing cores, coupled to a computer-readable medium (e.g., a non-transitory computer-readable medium), such as a memory 905. The memory 905 may store computer-readable instructions that are executable to cause the processor 904 to transform the physical device information 901 to comply with a file format and to generate a library file 906.

In a particular embodiment, the library file 906 includes at least one data file including the transformed design information. For example, the library file 906 may include a library of semiconductor devices including backside sensors, such as the semiconductor device 110 of FIG. 1, the semiconductor devices 210, 236 of FIG. 2, the semiconductor devices 310, 336 of FIG. 3, or a combination thereof, that is provided for use with an electronic design automation (EDA) tool 910.

The library file 906 may be used in conjunction with the EDA tool 910 at a design computer 907 including a processor 908, such as one or more processing cores, coupled to a memory 909. The EDA tool 910 may be stored as processor executable instructions at the memory 909 to enable a user of the design computer 907 to design a circuit including the semiconductor device 110 of FIG. 1, the semiconductor devices 210, 236 of FIG. 2, the semiconductor devices 310, 336 of FIG. 3, or a combination thereof, of the library file 906. For example, a user of the design computer 907 may enter circuit design information 911 via a user interface 912 coupled to the design computer 907. The circuit design information 911 may include design information representing at least one physical property of a semiconductor device, such as the semiconductor device 110 of FIG. 1, the semiconductor devices 210, 236 of FIG. 2, the semiconductor devices 310, 336 of FIG. 3, or a combination thereof. To illustrate, the circuit design property may include identification of particular circuits and relationships to other elements in a circuit design, positioning information, feature size information, interconnection information, or other information representing a physical property of a semiconductor device.

The design computer 907 may be configured to transform the design information, including the circuit design information 911, to comply with a file format. To illustrate, the file format may include a database binary file format representing planar geometric shapes, text labels, and other information about a circuit layout in a hierarchical format, such as a Graphic Data System (GDSII) file format. The design computer 907 may be configured to generate a data file including the transformed design information, such as a GDSII file 913 that includes information describing the semiconductor device 110 of FIG. 1, the semiconductor devices 210, 236 of FIG. 2, the semiconductor devices 310, 336 of FIG. 3, or a combination thereof, in addition to other circuits or information. To illustrate, the data file may include information corresponding to a system-in-package (SIP) or system-on-chip (SOC) that includes the semiconductor device 110 of FIG. 1, the semiconductor devices 210, 236 of FIG. 2, the semiconductor devices 310, 336 of FIG. 3, or a combination thereof, and that also includes additional electronic circuits and components within the SIP or SOC. For example, the data file may include information corresponding to one or more components of the packaged semiconductor device 100 of FIG. 1, the device 200 of FIG. 2, the device 300 of FIG. 3, or any combination thereof.

The GDSII file 913 may be received at a fabrication process 914 to manufacture the semiconductor device 110 of FIG. 1, the semiconductor devices 210, 236 of FIG. 2, the semiconductor devices 310, 336 of FIG. 3, or a combination thereof, according to transformed information in the GDSII file 913. For example, a device manufacture process may include providing the GDSII file 914 to a mask manufacturer 915 to create one or more masks, such as masks to be used with photolithography processing, illustrated as a representative mask 916. The mask 916 may be used during the fabrication process to generate one or more wafers 917, which may be tested and separated into dies, such as a representative die 942. The die 942 may include the semiconductor device 110 of FIG. 1, the semiconductor devices 210, 236 of FIG. 2, the semiconductor devices 310, 336 of FIG. 3, or a combination thereof.

For example, the fabrication process 914 may include a processor 918 and a memory 919 to initiate and/or control the fabrication process 914. The memory 919 may include executable instructions such as computer-readable instructions or processor-readable instructions. The executable instructions may include one or more instructions that are executable by the processor 918.

The fabrication process 914 may be implemented by a fabrication system that is fully automated or partially automated. For example, the fabrication process 914 may be automated according to a schedule. The fabrication system may include fabrication equipment (e.g., processing tools) to perform one or more operations to form a semiconductor device. For example, the fabrication equipment may be configured to form a stress sensor on a first side of a semiconductor device, form circuitry on a second side of a semiconductor device, and form a structure within the semiconductor device to provide data indicating stress detected by the stress sensor to an interface during a testing process associated with the semiconductor device, etc.

The fabrication system (e.g., an automated system that performs the fabrication process 914) may have a distributed architecture (e.g., a hierarchy). For example, the fabrication system may include one or more processors, such as the processor 918, one or more memories, such as the memory 919, and/or controllers that are distributed according to the distributed architecture. The distributed architecture may include a high-level processor that controls or initiates operations of one or more low-level systems. For example, a high-level portion of the fabrication process 914 may include one or more processors, such as the processor 918, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level system. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component may include a processor, such as the processor 918.

Alternatively, the processor 918 may be a part of a high-level system, subsystem, or component of the fabrication system. In another embodiment, the processor 918 is configured to perform distributed processing at various levels and components of a fabrication system.

Thus, the processor 918 may include processor-executable instructions that, when executed by the processor 918, cause the processor 918 to initiate or control formation of a semiconductor device by forming a stress sensor on a first side of a semiconductor device, forming circuitry on a second side of a semiconductor device, and forming a structure within the semiconductor device. The structure is configured to provide data indicating stress detected by the stress sensor to an interface during a testing process associated with the semiconductor device.

The executable instructions included in the memory 919 may enable the processor 918 to initiate formation of a semiconductor device, such as the semiconductor device 110 of FIG. 1, the semiconductor devices 210, 236 of FIG. 2, the semiconductor devices 310, 336 of FIG. 3, or a combination thereof. In a particular embodiment, the memory 919 is a non-transient computer-readable medium storing computer-executable instructions that are executable by the processor 918 to cause the processor 918 to initiate formation of a semiconductor device in accordance with at least a portion of any of the methods of FIGS. 4-7. The semiconductor device may be formed by forming a stress sensor on a first side of a semiconductor device, forming circuitry on a second side of a semiconductor device, and forming a structure within the semiconductor device to provide data indicating stress detected by the stress sensor to an interface during a testing process associated with the semiconductor device.

The die 920 may include a backside stress sensor 942. For example, the backside stress sensor may correspond to the stress sensor 120 of FIG. 1, one or more of the stress sensors 220-224 of FIG. 2, one or more of the stress sensors 320-324 of FIG. 3, or any combination thereof. The die 920 may be provided to a packaging process 921 where the die 920 is incorporated into a representative package 922.

The package 922 may include the single die 920 or multiple dies, such as a system-in-package (SiP) arrangement. The package 922 may be configured to conform to one or more standards or specifications, such as Joint Electron Device Engineering Council (JEDEC) standards. The package 922 may include a stress test interface 944. In an embodiment, the package 922 corresponds to the packaged semiconductor device 100 of FIG. 1, and the stress test interface 944 may correspond to the interface described with reference to FIGS. 4 and 5.

During the packaging process 921, one or more packaging test computers, such as a representative packaging test computer 950, may be used to test the die 920 and/or the package 922. The packaging test computer 950 may include a processor 952 coupled to a memory 954. In an embodiment, the memory 954 includes processor-readable instructions. The processor-readable instructions may be executable by the processor 952 to perform one or more tests. For example, the processor-readable instructions may be executable to perform the method 700 of FIG. 7. The processor 952 may initiate receiving data from the backside stress sensor 942 via the stress test interface 944. The data may include measurements 956 (e.g., stress measurements) and may be stored at the computer 950.

Information regarding the package 922 may be distributed to various product designers, such as via a component library stored at a computer 925. The computer 925 may include a processor 926, such as one or more processing cores, coupled to a memory 927. A printed circuit board (PCB) tool may be stored as processor executable instructions at the memory 927 to process PCB design information 923 received from a user of the computer 925 via a user interface 924. The PCB design information 923 may include physical positioning information of a packaged semiconductor device on a circuit board, the packaged semiconductor device corresponding to the package 922. The package 922 may correspond to the package 102 of FIG. 1. The package 922 may include the semiconductor device 110 of FIG. 1, the semiconductor devices 210, 236 of FIG. 2, the semiconductor devices 310, 336 of FIG. 3, or a combination thereof.

The computer 925 may be configured to transform the PCB design information 923 to generate a data file, such as a GERBER file 928 with data that includes physical positioning information of a packaged semiconductor device on a circuit board, as well as layout of electrical connections such as traces and vias, where the packaged semiconductor device corresponds to the package 922 and may include the semiconductor device 110 of FIG. 1, the semiconductor devices 210, 236 of FIG. 2, the semiconductor devices 310, 336 of FIG. 3, or a combination thereof. In other embodiments, the data file generated by the transformed PCB design information may have a format other than a GERBER format.

The GERBER file 928 may be received at a board assembly process 929 and used to create PCBs, such as a representative PCB 929, manufactured in accordance with the design information stored within the GERBER file 928. For example, the GERBER file 928 may be uploaded to one or more machines to perform various steps of a PCB production process. The PCB 929 may be populated with electronic components including the package 922 to form a representative printed circuit assembly (PCA) 931.

During the board assembly process 929, one or more assembly test computers, such as a representative assembly test computer 960, may be used to test the die 920 and/or the package 922. The assembly test computer 960 may include a processor 962 coupled to a memory 964. In an embodiment, the memory 964 includes processor-readable instructions. The processor-readable instructions may be executable by the processor 962 to perform one or more tests. For example, the processor-readable instructions may be executable to perform the method 700 of FIG. 7. The processor 962 may receive data from the backside stress sensor 942 via the stress test interface 944. The data may include measurements 966 (e.g., stress measurements) and may be stored at the computer 960. Although certain packaging operations have been described, a semiconductor device (e.g., including the backside stress sensor 942) can be mounted on a printed circuit board using a surface-mount process, such as in connection with a chip-on-board (COB) configuration.

The PCA 931 may be received at a product manufacture process 932 and integrated into one or more electronic devices, such as a first representative electronic device 933 and a second representative electronic device 934. For example, the first representative electronic device 933, the second representative electronic device 934, or both, may include or correspond to the electronic device 800 of FIG. 8. As an illustrative, non-limiting example, the first representative electronic device 933, the second representative electronic device 934, or both, may include a communications device, a fixed location data unit, a mobile location data unit, a mobile phone, a cellular phone, a satellite phone, a computer, a tablet, a portable computer, or a desktop computer. Alternatively or additionally, the first representative electronic device 933, the second representative electronic device 934, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof, into which the semiconductor device 110 of FIG. 1, the semiconductor devices 210, 236 of FIG. 2, the semiconductor devices 310, 336 of FIG. 3, or a combination thereof, is integrated. As another illustrative, non-limiting example, one or more of the electronic devices 933 and 934 may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 9 illustrates remote units according to teachings of the disclosure, the disclosure is not limited to these illustrated units. Embodiments of the disclosure may be suitably employed in any device which includes active integrated circuitry including memory and on-chip circuitry.

A device that includes the semiconductor device 110 of FIG. 1, the first semiconductor device 210 of FIG. 2, the first semiconductor device 310 of FIG. 3, or a combination thereof, may be fabricated, processed, and incorporated into an electronic device, as described in the illustrative process 900. One or more aspects of the embodiments disclosed with respect to FIGS. 1-8 may be included at various processing stages, such as within the library file 906, the GDSII file 913 (e.g., a file having a GDSII format), and the GERBER file 928 (e.g., a file having a GERBER format), as well as stored at the memory 905 of the research computer 903, the memory 909 of the design computer 907, the memory 927 of the computer 925, the memory 954 of the packaging test computer 950, the memory 964 of the assembly test computer 960, the memory of one or more other computers or processors (not shown) used at the various stages, and also incorporated into one or more other devices such as the mask 916, the die 920, the package 922, the PCA 931, other products such as prototype circuits or devices (not shown), or any combination thereof. Although various representative stages of production from a physical device design to a final product are depicted, in other embodiments fewer stages may be used or additional stages may be included. Similarly, the process 900 may be performed by a single entity or by one or more entities performing various stages of the process 900.

Although one or more of FIGS. 1-9 may illustrate systems, apparatuses, and/or methods according to the teachings of the disclosure, the disclosure is not limited to these illustrated systems, apparatuses, and/or methods. Embodiments of the disclosure may be suitably employed in any device that includes integrated circuitry including memory, a processor, and on-chip circuitry.

One or more functions or components of any of FIGS. 1-9 as illustrated or described herein may be combined with one or more other portions of another of FIGS. 1-9. Accordingly, no single embodiment described herein should be construed as limiting and embodiments of the disclosure may be suitably combined without departing from the teachings of the disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
a stress sensor located on a first side of a semiconductor device; and
circuitry located on a second side of the semiconductor device,
wherein the stress sensor is configured to detect stress at the semiconductor device.

2. The apparatus of claim 1, wherein the stress sensor is configured to detect stress imposed on the circuitry.

3. The apparatus of claim 2, wherein the circuitry comprises an analog circuit.

4. The apparatus of claim 1, further comprising a package, wherein the semiconductor device, the stress sensor, and the circuitry are integrated within the package.

5. The apparatus of claim 4, further comprising a second semiconductor device that is integrated within the package, wherein the stress sensor is configured to detect stress imposed on the semiconductor device by the second semiconductor device.

6. The apparatus of claim 1, further comprising a connector formed on the second side of the semiconductor device, the connector configured to couple the second side of the semiconductor device to a substrate via a flip chip process during an assembly process that connects the semiconductor device to the substrate.

7. The apparatus of claim 6, wherein the connector comprises a flip chip bump, and wherein the stress sensor is configured to detect stress imposed on the semiconductor device by the flip chip bump during the assembly process.

8. The apparatus of claim 6, wherein the substrate is a surface of a package.

9. The apparatus of claim 1, wherein the semiconductor device comprises a substrate and one or more layers formed on the substrate, wherein the circuitry is formed on a frontside of the substrate, and wherein the stress sensor is formed on a back side of the substrate.

10. The apparatus of claim 1, further comprising:
second circuitry formed on the second side of the semiconductor device, the stress sensor configured to detect stress imposed on the second circuitry;
a second semiconductor device; and
a second stress sensor configured to detect stress imposed on the semiconductor device by the second semiconductor device.

11. The apparatus of claim 1, further comprising an electronic device selected from a mobile device, a computer, a set top box, a music player, a video player, an entertainment unit, a navigation device, a communications device, a personal digital assistant (PDA), or a fixed location data unit, wherein the semiconductor device, the stress sensor, and the circuitry are integrated within the electronic device.

12. The apparatus of claim 1, wherein the stress sensor comprises an oxide thin film layer.

13. The apparatus of claim 12, wherein the oxide thin film layer comprises indium tin oxide.

14. The apparatus of claim 1, further comprising a stress test interface of a package that includes the semiconductor device, wherein the interface is configured to provide stress measurements generated by the stress sensor to an assembly test computer during a test associated with the semiconductor device.

15. The apparatus of claim 14, wherein the semiconductor device includes a through-silicon via that is coupled to the stress sensor.

16. The apparatus of claim 14, further comprising a wire, wherein the wire is connected to the interface and further connected to the stress sensor via a redistribution layer of the semiconductor device, the wire configured to provide the stress measurements from the stress sensor to the interface.

17. A method comprising:
receiving data from a stress sensor located on a first side of a packaged semiconductor device, the packaged semiconductor device including circuitry located on a second side of the packaged semiconductor device, wherein the data indicates stress detected by the stress sensor; and
performing a test associated with the packaged semiconductor device based on the data.

18. The method of claim 17, wherein a processor of a test computer executes instructions to perform the test by comparing the data to a stress threshold.

19. The method of claim 17, further comprising performing an assembly process prior to performing the test, wherein performing the assembly process comprises packaging a semiconductor device within a package to assemble the packaged semiconductor device.

20. The method of claim 19, wherein the semiconductor device is mounted within the package using a flip chip packaging process.

21. The method of claim 17, wherein the data is received at a test computer that comprises a processor and a memory, and wherein the test is performed by the test computer.

22. A computer-readable medium storing instructions that are executable by a processor to initiate or control operations during a fabrication process, the operations comprising:
forming a stress sensor on a first side of a semiconductor device;
forming circuitry on a second side of the semiconductor device; and
forming a structure within the semiconductor device, the structure configured to provide data indicating stress detected by the stress sensor to a testing computer during a test associated with the semiconductor device.

23. The computer-readable medium of claim 22, wherein the structure comprises a through-silicon via or a redistribution layer.

24. The computer-readable medium of claim 22, wherein the operations further comprise forming a connector on the second side of the semiconductor device.

25. The computer-readable medium of claim 24, wherein the instructions are further executable by the processor to initiate or control an assembly process to integrate the semiconductor device within a package, and wherein the assembly process couples the connector to a surface of the package using a flip chip packaging technique.

26. The computer-readable medium of claim 25, wherein the assembly process comprises connecting a wire between the structure and an interface of the package.

27. The computer-readable medium of claim 26, wherein the interface is to provide the data to a test computer during the test and after completing the fabrication process.

28. An apparatus comprising:
means for sensing stress at a semiconductor device, wherein the means for sensing stress is located on a first side of the semiconductor device; and
means for performing circuit operations, wherein the means for performing circuit operations is located on a second side of the semiconductor device.

29. The apparatus of claim 28, wherein the means for sensing stress comprises a stress sensor, and wherein the means for performing circuit operations comprises an analog circuit.

30. The apparatus of claim 28, further comprising an electronic device selected from a mobile device, a computer, a set top box, a music player, a video player, an entertainment unit, a navigation device, a communications device, a personal digital assistant (PDA), or a fixed location data unit, wherein the means for sensing, and the means for performing circuit operations are integrated within the electronic device.
